(19) United States
(12) Patent Application Publication
(10) Pub. No.: US 2025/0132129 A1
(43) Pub. Date: Apr. 24, 2025

(54) FREQUENCY CONTROL OF SOURCE RADIO FREQUENCY POWER IN PLASMA PROCESSING

(71) Applicant: Tokyo Electron Limited, Tokyo (JP)

(72) Inventor: Chishio KOSHIMIZU, Kurokawa-gun (JP)

(21) Appl. No.: 19/000,700

(22) Filed: Dec. 24, 2024

Related U.S. Application Data
(63) Continuation of application No. PCT/JP2023/034969, filed on Sep. 26, 2023.

(30) Foreign Application Priority Data
Oct. 7, 2022 (JP) 2022-162643
Nov. 7, 2022 (JP) 2022-178137

(51) Int. Cl. H01J 37/32

(52) U.S. Cl. CPC H01J 37/32155; H01J 37/32174; H01J 37/32091

(57) ABSTRACT

A disclosed plasma processing apparatus includes a chamber, a radio frequency power supply, and circuitry. The radio frequency power supply is configured to supply a source radio frequency power to generate a plasma from a gas in the chamber. The circuitry is configured to set a source frequency of the source radio frequency power when the source radio frequency power is supplied alone to suppress a degree of reflection of the source radio frequency power in accordance with the source frequency and the degree of reflection of the source radio frequency power when the source radio frequency power is supplied alone beforehand.

### CROSS-REFERENCE TO RELATED APPLICATIONS

This application is a continuation application of PCT Application No. PCT/JP2023/034969, filed on Sep. 26, 2023, which claims the benefit of priority from Japanese Patent Application No. 2022-178137, filed on Nov. 7, 2022, and Japanese Patent Application No. 2022-162643, filed on Oct. 7, 2022. The entire contents of the above listed PCT and priority applications are incorporated herein by reference.

### BACKGROUND

### Field

The present disclosure relates to a plasma processing apparatus, a power supply system, and a frequency control method.

### Description of the Related Art

A plasma processing apparatus is used in plasma processing to be performed on a substrate. The plasma processing apparatus generates plasma from a gas in a chamber by supplying a source radio frequency power. The plasma processing apparatus uses a bias radio frequency power to attract ions from the plasma generated in the chamber into the substrate. Japanese Unexamined Patent Publication No. 2009-246091 discloses a plasma processing apparatus that modulates a power level and a frequency of a bias radio frequency power.

### SUMMARY

Disclosed herein is a plasma processing apparatus. The plasma processing apparatus may include a chamber, a radio frequency power supply, and circuitry. The radio frequency power supply is configured to supply a source radio frequency power to generate a plasma from a gas in the chamber. The circuitry is configured to set a source frequency of the source radio frequency power when the source radio frequency power is supplied alone to suppress a degree of reflection of the source radio frequency power in accordance with the source frequency and the degree of reflection of the source radio frequency power when the source radio frequency power is supplied alone beforehand.

### BRIEF DESCRIPTION OF THE DRAWINGS

FIG. 1 is a block diagram illustrating a computer-based system that functions as a controller that controls processing executed in an example of the present disclosure.

FIG. 2 is a diagram illustrating a configuration example of a plasma processing system.

FIG. 3 is a diagram illustrating a configuration example of a capacitively coupled plasma processing apparatus.

FIG. 4 is an example timing chart related to a plasma processing apparatus according to an example.

FIG. 5 is a flowchart illustrating a frequency control method according to an example.

FIG. 6 is an example timing chart related to a plasma processing apparatus according to another example.

FIG. 7 is an example timing chart related to a plasma processing apparatus according to still another example.

FIG. 8 is an example timing chart related to a plasma processing apparatus according to still another example.

FIG. 9 is an example timing chart related to a plasma processing apparatus according to still another example.

FIG. 10 is an example timing chart related to a plasma processing apparatus according to still another example.

FIG. 11 is a flowchart illustrating a frequency control method according to another example.

### DETAILED DESCRIPTION

According to an aspect of the present disclosure, a new apparatus and method are disclosed for using pulsed high-frequency (HF) RF while generating plasma to quickly stabilize the plasma.

In an example of the present disclosure, a HF power source supplies pulsed power for generation of plasma under control of a controller.

A plasma processing apparatus according to one example may include a chamber, a radio frequency power supply, and a controller. The radio frequency power supply is configured to supply a source radio frequency power to generate a plasma from a gas in the chamber. The controller is configured to set a source frequency of the source radio frequency power when the source radio frequency power is supplied alone to suppress a degree of reflection of the source radio frequency power in accordance with the source frequency and the degree of reflection of the source radio frequency power when the source radio frequency power is supplied alone beforehand.

As used herein, an element or step recited in the singular and proceeded with the word “a” or “an” should be understood as not excluding plural elements or steps, unless such exclusion is explicitly recited. Furthermore, references to “one example” of the present invention are not intended to be interpreted as excluding the existence of additional examples that also incorporate the recited features.

Control methods and systems described herein may be implemented using computer programming or engineering techniques including computer software, firmware, hardware or any combination or subset thereof, wherein the technical effects may include at least processing of a substrate in a plasma processing apparatus using a controller to control pulsed high-frequency (HF) RF while generating the plasma.

In the following description, with reference to the drawings, the same reference numbers are assigned to the same components or to similar components having the same function, and overlapping description is omitted.

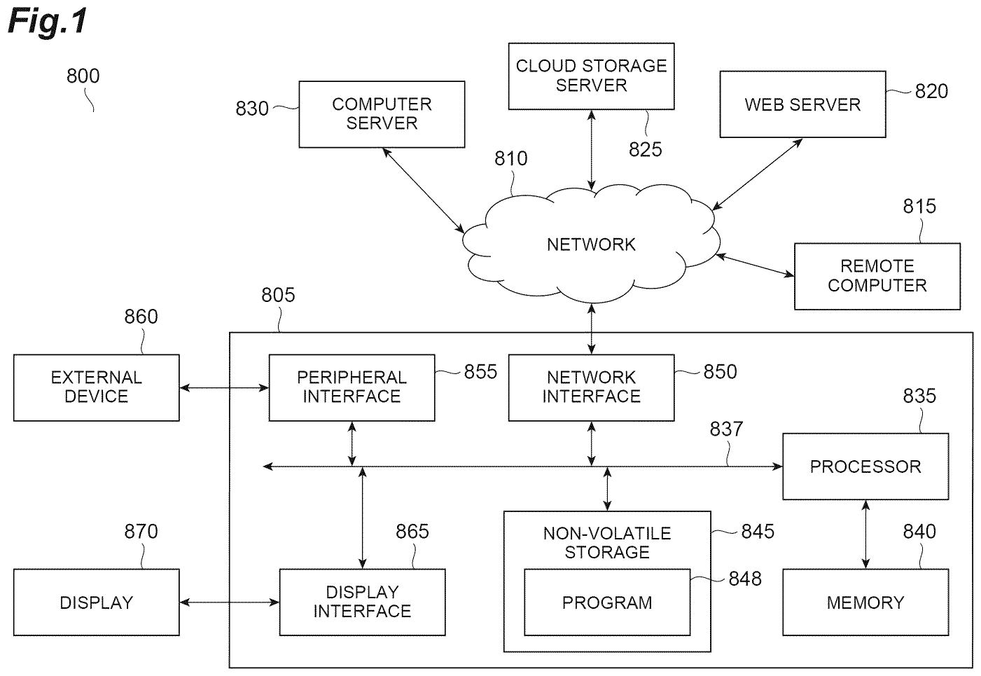

FIG. 1 illustrates a block diagram of a computer (as one type of circuitry) that may implement the various control aspects of examples.

Control aspects of the present disclosure may be embodied as a system, a method, and/or a computer program product. The computer program product may include a computer readable storage medium on which computer readable program instructions are recorded that may cause one or more processors to carry out aspects of the example.

The computer readable storage medium may be a tangible device that can store instructions for use by an instruction execution device (processor). The computer readable storage medium may be, for example, but is not limited to, an electronic storage device, a magnetic storage device, an optical storage device, an electromagnetic storage device, a semiconductor storage device, or any appropriate combination of these devices. A non-exhaustive list of more specific examples of the computer readable storage medium includes each of the following (and appropriate combinations): flexible disk, hard disk, solid-state drive (SSD), random access memory (RAM), read-only memory (ROM), erasable programmable read-only memory (EPROM or Flash), static random access memory (SRAM), compact disc (CD or CD-ROM), digital versatile disk (DVD) and memory card or stick. A computer readable storage medium, as used in this disclosure, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described in this disclosure can be downloaded to an appropriate computing or processing device from a computer readable storage medium or to an external computer or external storage device via a global network (i.e., the Internet), a local area network, a wide area network and/or a wireless network. The network may include copper transmission wires, optical communication fibers, wireless transmission, routers, firewalls, switches, gateway computers and/or edge servers. A network adapter card or network interface in each computing or processing device may receive computer readable program instructions from the network and forward the computer readable program instructions for storage in a computer readable storage medium within the computing or processing device.

Computer readable program instructions for carrying out operations of the present disclosure may include machine language instructions and/or microcode, which may be compiled or interpreted from source code written in any combination of one or more programming languages, including assembly language, Basic, Fortran, Java, Python, R, C, C++, C# or similar programming languages. The computer readable program instructions may execute entirely on a user's personal computer, notebook computer, tablet, or smartphone, entirely on a remote computer or computer server, or any combination of these computing devices. The remote computer or computer server may be connected to the user's device or devices through a computer network, including a local area network or a wide area network, or a global network (i.e., the Internet). In some examples, electronic circuitry including, for example, programmable logic circuitry, field-programmable gate arrays (FPGA), or programmable logic arrays (PLA) may execute the computer readable program instructions by using information from the computer readable program instructions to configure or customize the electronic circuitry, in order to perform aspects of the present disclosure.

Aspects of the present disclosure are described herein with reference to flow diagrams and block diagrams of methods, apparatus (systems), and computer program products according to examples of the disclosure. It will be understood by those skilled in the art that each block of the flow diagrams and block diagrams, and combinations of blocks in the flow diagrams and block diagrams, can be implemented by computer readable program instructions.

The computer readable program instructions that may implement the systems and methods described in this disclosure may be provided to one or more processors (and/or one or more cores within a processor) of a general purpose computer, special purpose computer, or other programmable apparatus to produce a machine, such that the instructions, which execute via the processor of the computer or other programmable apparatus, create a system for implementing the functions specified in the flow diagrams and block diagrams in the present disclosure. These computer readable program instructions may also be stored in a computer readable storage medium that can direct a computer, a programmable apparatus, and/or other devices to function in a particular manner, such that the computer readable storage medium having stored instructions is an article of manufacture including instructions which implement aspects of the functions specified in the flow diagrams and block diagrams in the present disclosure.

The computer readable program instructions may also be loaded onto a computer, other programmable apparatus, or other device to cause a series of operational steps to be performed on the computer, other programmable apparatus or other device to produce a computer implemented process, such that the instructions which execute on the computer, other programmable apparatus, or other device implement the functions specified in the flow diagrams and block diagrams in the present disclosure.

FIG. 1 is a functional block diagram illustrating a networked system 800 of one or more networked computers and servers. In an example, the hardware and software environment illustrated in FIG. 1 may provide an example platform for implementation of the software and/or methods according to the present disclosure.

Referring to FIG. 1, a networked system 800 may include, but is not limited to, computer 805, network 810, remote computer 815, web server 820, cloud storage server 825 and computer server 830. In some examples, multiple instances of one or more of the functional blocks illustrated in FIG. 1 may be employed.

Additional detail of computer 805 is shown in FIG. 1. The functional blocks illustrated within computer 805 are provided only to establish exemplary functionality and are not intended to be exhaustive. And while details are not provided for remote computer 815, web server 820, cloud storage server 825 and computer server 830, these other computers and devices may include similar functionality to that shown for computer 805.

Computer 805 may be a personal computer (PC), a desktop computer, laptop computer, tablet computer, netbook computer, a personal digital assistant (PDA), a smart phone, or any other programmable electronic device capable of communicating with other devices on network 810.

Computer 805 may include processor 835, bus 837, memory 840, non-volatile storage 845, network interface 850, peripheral interface 855 and display interface 865. Each of these functions may be implemented, in some examples, as individual electronic subsystems (integrated circuit chip or combination of chips and associated devices), or, in other examples, some combination of functions may be implemented on a single chip (sometimes called a system on chip or SoC).

Processor 835 may be one or more single or multi-chip microprocessors, such as those designed and/or manufactured by Intel Corporation, Advanced Micro Devices, Inc. (AMD), Arm Holdings (Arm), Apple Computer, etc. Examples of microprocessors include Celeron, Pentium, Core i3, Core i5 and Core i7 from Intel Corporation; Opteron, Phenom, Athlon, Turion and Ryzen from AMD; and Cortex-A, Cortex-R and Cortex-M from Arm.

Bus 837 may be a proprietary or industry standard high-speed parallel or serial peripheral interconnect bus, such as ISA, PCI, PCI Express (PCI-e), AGP, and the like.

Memory 840 and non-volatile storage 845 may be computer-readable storage media. Memory 840 may include any suitable volatile storage devices such as Dynamic Random Access Memory (DRAM) and Static Random Access Memory (SRAM). Non-volatile storage 845 may include one or more of the following: flexible disk, hard disk, solid-state drive (SSD), read-only memory (ROM), erasable programmable read-only memory (EPROM or Flash), compact disc (CD or CD-ROM), digital versatile disk (DVD) and memory card or stick.

Program 848 may be a collection of machine readable instructions and/or data that is stored in non-volatile storage 845 and is used to create, manage and control certain software functions that are discussed in detail elsewhere in the present disclosure and illustrated in the drawings. In some examples, memory 840 may be considerably faster than non-volatile storage 845. In such examples, program 848 may be transferred from non-volatile storage 845 to memory 840 prior to execution by processor 835.

Computer 805 may be capable of communicating and interacting with other computers via network 810 through network interface 850. Network 810 may be, for example, a local area network (LAN), a wide area network (WAN) such as the Internet, or a combination of the two, and may include wired, wireless, or fiber optic connections. In general, network 810 can be any combination of connections and protocols that support communications between two or more computers and related devices.

Peripheral interface 855 may allow for input and output of data with other devices that may be connected locally with computer 805. For example, peripheral interface 855 may provide a connection to external devices 860. External devices 860 may include devices such as a keyboard, a mouse, a keypad, a touch screen, and/or other suitable input devices. External devices 860 may also include portable computer-readable storage media such as, for example, thumb drives, portable optical or magnetic disks, and memory cards. Software and data used to practice examples of the present disclosure, for example, program 848, may be stored on such portable computer-readable storage media. In such examples, software may be loaded onto non-volatile storage 845 or, alternatively, directly into memory 840 via peripheral interface 855. Peripheral interface 855 may use an industry standard connection, such as RS-232 or Universal Serial Bus (USB), to connect with external devices 860.

Display interface 865 may connect computer 805 to display 870. Display 870 may be used, in some examples, to present a command line or graphical user interface to a user of computer 805. Display interface 865 may connect to display 870 using one or more proprietary or industry standard connections, such as VGA, DVI, DisplayPort and HDMI.

As described above, network interface 850 provides for communications with other computing and storage systems or devices external to computer 805. Software programs and data discussed herein may be downloaded from, for example, remote computer 815, web server 820, cloud storage server 825 and computer server 830 to non-volatile storage 845 through network interface 850 and network 810. Furthermore, the systems and methods described in this disclosure may be executed by one or more computers connected to computer 805 through network interface 850 and network 810. For example, in some examples the systems and methods described in this disclosure may be executed by remote computer 815, computer server 830, or a combination of the interconnected computers on network 810.

Data, datasets and/or databases employed in examples of the systems and methods described in this disclosure may be stored and or downloaded from remote computer 815, web server 820, cloud storage server 825 and computer server 830.

Circuitry as used in the present application can be defined as one or more of the following: an electronic component (such as a semiconductor device), multiple electronic components that are directly connected to one another or interconnected via electronic communications, a computer, a network of computer devices, a remote computer, a web server, a cloud storage server, a computer server. For example, each of the one or more of the computer, the remote computer, the web server, the cloud storage server, and the computer server can be encompassed by or may include the circuitry as a component(s) thereof. In some examples, multiple instances of one or more of these components may be employed, wherein each of the multiple instances of the one or more of these components are also encompassed by or include circuitry. In some examples, the circuitry represented by the networked system may include a serverless computing system corresponding to a virtualized set of hardware resources. The circuitry represented by the computer may be a personal computer (PC), a desktop computer, a laptop computer, a tablet computer, a netbook computer, a personal digital assistant (PDA), a smart phone, or any other programmable electronic device capable of communicating with other devices on the network. The circuitry may be a general purpose computer, special purpose computer, or other programmable apparatus as described herein that includes one or more processors. Each processor may be one or more single or multi-chip microprocessors. Processors are considered processing circuitry or circuitry as they include transistors and other circuitry therein. The circuitry may implement the systems and methods described in this disclosure based on computer-readable program instructions provided to the one or more processors (and/or one or more cores within a processor) of one or more of the general purpose computer, special purpose computer, or other programmable apparatus described herein to produce a machine, such that the instructions, which execute via the one or more processors of the programmable apparatus that is encompassed by or includes the circuitry, create a system for implementing the functions specified in the flow diagrams and block diagrams in the present disclosure. Alternatively, the circuitry may be a preprogrammed structure, such as a programmable logic device, application specific integrated circuit, or the like, and is/are considered circuitry regardless if used in isolation or in combination with other circuitry that is programmable, or preprogrammed.

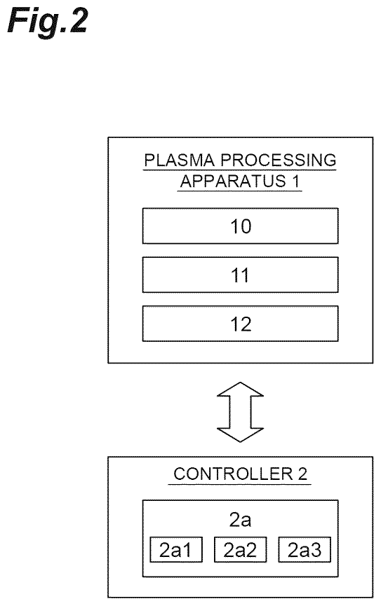

FIG. 2 illustrates an example configuration of a plasma processing system. In one example, the plasma processing system includes a plasma processing apparatus 1 and a controller 2. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in a plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator.

The controller 2 processes computer executable instructions causing the plasma processing apparatus 1 to perform various operations described in this disclosure. The controller 2 may be configured to control individual components of the plasma processing apparatus 1 such that these components execute the various operations. In an example, the controller 2 may be partially or entirely incorporated into the plasma processing apparatus 1. In an example, the controller 2 may include a computer 2a. In an example, the computer 2a may include a processor (CPU: Central Processing Unit) 2a1, a storage 2a2, and a communication interface 2a3. The processor 2al may be configured to perform various controlling operations in accordance with a program stored in the storage 2a2. The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN).

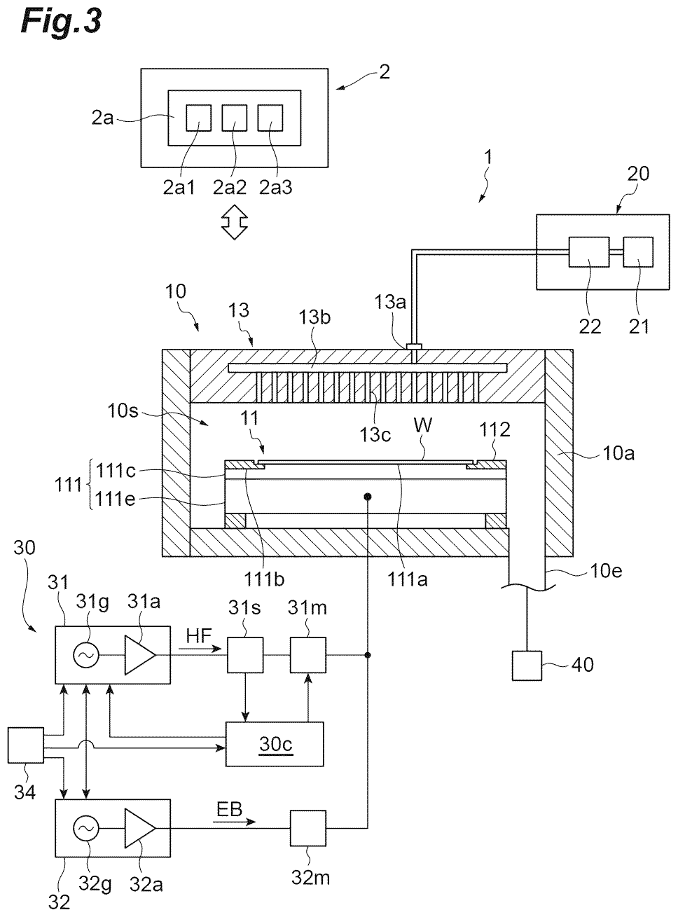

An example configuration of a capacitively coupled plasma processing apparatus, which is an example of the plasma processing apparatus 1, will now be described. FIG. 3 illustrates an example configuration of the capacitively coupled plasma processing apparatus.

The capacitively coupled plasma processing apparatus 1 includes a plasma processing chamber 10, a gas supply 20, a power supply system 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in a plasma processing chamber 10. The showerhead 13 is disposed above the substrate support 11. In an example, the showerhead 13 configures at least a part of the ceiling of the plasma processing chamber 10. The plasma processing chamber 10 has a plasma processing space 10s that is defined by the showerhead 13, the sidewall 10a of the plasma processing chamber 10, and the substrate support 11. The sidewall 10a is grounded. The showerhead 13 and the substrate support 11 are electrically insulated from the housing of the plasma processing chamber 10.

The substrate support 11 includes a body 111 and a ring assembly 112. The body 111 has a central region 111a or a substrate supporting surface for supporting a substrate W or wafer and an annular region 111b or a ring supporting surface for supporting the ring assembly 112. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. In an example, the body 111 includes a base 111e and an electrostatic chuck 111c. The base Ille includes a conductive member. The conductive member of the base 111e can function as a lower electrode. The electrostatic chuck 111c is disposed on the base 111e. An upper surface of the electrostatic chuck 111c includes the substrate supporting surface 111a. The ring assembly 112 includes one or more annular members. At least one of the annular members is an edge ring. The substrate support 11 may also include a temperature adjusting module (not shown) that is configured to adjust at least one of the electrostatic chuck 111c, the ring assembly 112, and the substrate W to a target temperature. The temperature adjusting module may be a heater, a heat transfer medium, a flow passage, or any combination thereof. A heat transfer fluid, such as brine or gas, flows into the flow passage. The substrate support 11 may further include a heat transfer gas supply configured to supply a heat transfer gas to a gap between the rear surface of the substrate W and the substrate supporting surface 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes a conductive member. The conductive member of the showerhead 13 functions as an upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an example, the gas supply 20 is configured to supply at least one process gas from the corresponding gas source 21 through the corresponding flow controller 22 into the showerhead 13. Each flow controller 22 may include, for example, a mass flow controller or a pressure-controlled flow controller. The gas supply 20 may include a flow modulation device that can modulate or pulse the flow of the at least one process gas.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

The plasma processing apparatus 1 further includes a power supply system 30. The power supply system 30 includes a radio frequency power supply 31 and a controller 30c. The power supply system 30 may further include a bias power supply 32. The power supply system 30 may further include one or more sensors 31s.

The radio frequency power supply 31 is configured to generate a source radio frequency power HF to generate a plasma in a chamber (plasma processing chamber 10). The source radio frequency power HF has a source frequency f_{S}. The source frequency f_{S} is, for example, a frequency in a range of 13 MHz or higher and 200 MHz or lower. The source frequency f_{S} may be set to 27 MHz, 40.68 MHz, 60 MHZ, or 100 MHz. A power level of the source radio frequency power HF is, for example, 500 W or higher and 20 kW or lower.

In an example, the radio frequency power supply 31 may include a radio frequency signal generator 31g and an amplifier 31a. The radio frequency signal generator 31g generates a radio frequency signal. The amplifier 31a generates the source radio frequency power HF by amplifying the radio frequency signal input from the radio frequency signal generator 31g, and outputs the source radio frequency power HF. The radio frequency signal generator 31g may be configured by a programmable logic device, such as a programmable processor or an FPGA. Further, a D/A converter may be connected between the radio frequency signal generator 31g and the amplifier 31a.

The radio frequency power supply 31 is connected to a radio frequency electrode via a matcher 31m. A base 111e configures the radio frequency electrode in an example. In another example, the radio frequency electrode may be an electrode provided in an electrostatic chuck 111c. The radio frequency electrode may be an electrode common to a bias electrode described later. Alternatively, the radio frequency electrode may be the upper electrode. The matcher 31m includes a matching circuit. The matching circuit of the matcher 31m has variable impedance. The matching circuit of the matcher 31m is controlled by the controller 30c. The impedance of the matching circuit of the matcher 31m is adjusted to match impedance on a load side of the radio frequency power supply 31 to output impedance of the radio frequency power supply 31.

The one or more sensors 31s may be connected between the radio frequency power supply 31 and the matcher 31m. The one or more sensors 31s may be connected between the matcher 31m and the radio frequency electrode. For example, the one or more sensors 31s may be connected between the bias electrode and a junction of an electrical path extending from the matcher 31m to the bias electrode and an electrical path extending from a matcher 32m, which will be described later, to the bias electrode. Alternatively, the one or more sensors 31s may be connected between the junction and the matcher 31m. The one or more sensors 31s may be sensors separated from the matcher 31m or may be a part of the matcher 31m.

The one or more sensors 31s may include a directional coupler. The directional coupler is configured to detect a power level of a reflected wave of the source radio frequency power HF returned from the load of the radio frequency power supply 31, and notify the controller 30c of the detected power level of the reflected wave.

Further, the one or more sensors 31s may include a VI sensor. The VI sensor is configured to detect a voltage V_{HF} and a current I_{HF} of the source radio frequency power, and determine impedance Z_{L} on the load side of the radio frequency power supply 31 from the voltage VHF and the current I_{HF}. The VI sensor may be configured to determine a phase difference between the voltage V_{HF} and the current I_{HF}.

The bias power supply 32 is electrically coupled to the bias electrode. In an example, the base Ille configures the bias electrode. In another example, the bias electrode may be an electrode provided in the electrostatic chuck 111c. The bias power supply 32 is configured to apply an electric bias EB (or bias energy) to the bias electrode. The bias power supply 32 may be configured to apply a pulse of the electric bias EB to the bias electrode. In this case, the bias power supply 32 may determine a timing of each of a plurality of pulses by using a signal applied from a pulse controller 34. The controller 2 may function as the pulse controller 34.

The electric bias EB has a waveform cycle. That is, the electric bias EB is periodically applied to the bias electrode at a time interval of the waveform cycle. The waveform cycle of the electric bias EB is the shortest cycle of the waveform of the electric bias EB, and has a time length that is the reciprocal of a bias frequency of the electric bias EB. The bias frequency may be lower than the source frequency. The bias frequency may be 100 kHz or higher and 28 MHz or lower, and may be, for example, 400 kHz or 3.2 MHZ.

In an example, the electric bias EB may be a bias radio frequency power having the bias frequency. In this case, the bias power supply 32 is connected to the bias electrode via the matcher 32m. The matcher 32m includes a matching circuit. The matching circuit of the matcher 32m has variable impedance. The matching circuit of the matcher 32m is controlled by the controller 30c. The impedance of the matching circuit of the matcher 32m is adjusted to match impedance on a load side of the bias power supply 32 to output impedance of the bias power supply 32. The power level of the bias radio frequency power may be 500 W or higher and 50 kW or lower.

In another example, the electric bias EB may include a pulse of a voltage that is periodically applied to the bias electrode at the time interval of the waveform cycle. The voltage pulse may be a negative voltage pulse or a negative direct current voltage pulse (a pulse generated by applying waveform generation to a negative direct current voltage), or may be another voltage pulse. The voltage pulse may have a waveform, such as a triangular wave or a rectangular wave. The voltage pulse may have any other pulse waveforms. When the voltage pulse is used as the electric bias EB, the plasma processing apparatus 1 does not include the matcher 32m.

The bias power supply 32 may include a signal generator 32g and an amplifier 32a. The signal generator 32g then generates a signal for generating the electric bias EB. The amplifier 32a generates the electric bias EB by amplifying the signal input from the signal generator 32g, to supply the generated electric bias EB to the bias electrode. The signal generator 32g may be configured by a programmable logic device, such as a programmable processor or an FPGA. Further, a D/A converter may be connected between the signal generator 32g and the amplifier 32a.

The bias power supply 32 is synchronized with the radio frequency power supply 31. A synchronization signal used to synchronization may be supplied from the bias power supply 32 to the radio frequency power supply 31. Alternatively, the synchronization signal may be supplied from the radio frequency power supply 31 to the bias power supply 32. Alternatively, the synchronization signal may be supplied to the radio frequency power supply 31 and the bias power supply 32 from another device, such as the controller 30c.

The controller 30c is configured to control the radio frequency power supply 31. The controller 30c may be configured by a processor, such as a CPU. The controller 30c may be a part of the matcher 31m, may be a part of the radio frequency power supply 31, or may be a controller separated from the matcher 31m and the radio frequency power supply 31. Alternatively, the controller 2 may also serve as the controller 30c.

In various examples, the controller 30c sets the source frequency f_{S} in a period P_{HO} (single supply period) during which the source radio frequency power HF is supplied alone to generate the plasma in the chamber 10 to suppress a degree of reflection of the source radio frequency power HF. The controller 30c sets the source frequency f_{S} at each time point in the period P_{HO} to suppress the degree of reflection of the source radio frequency power HF, in accordance with the source frequency f_{S} and the degree of reflection of the source radio frequency power HF when the source radio frequency power HF is supplied alone. The period P_{HO} is a period during which the electric bias EB is not supplied and the source radio frequency power HF is supplied alone beforehand.

In various examples, the degree of reflection may be acquired as the power level of the reflected wave of the source radio frequency power HF. The degree of reflection may be acquired as a value of a ratio of the power level of the reflected wave of the source radio frequency power HF to a power level of a traveling wave of the source radio frequency power HF or a set output power level of the source radio frequency power HF. Alternatively, the degree of reflection may be acquired as a deviation amount of the impedance Z_{L} with respect to characteristic impedance (for example, 50Ω) of a power feed line to the radio frequency electrode of the source radio frequency power HF. Alternatively, the degree of reflection may be acquired as the phase difference between the voltage V_{HF} and the current I_{HF}. Alternatively, the degree of reflection may be acquired as another quantity representing a degree of matching with the plasma at the source frequency f_{S}. In any case, the degree of reflection may be acquired by the one or more sensors 31s or may be determined from measured values acquired by one or more sensors 31s.

Hereinafter, various examples related to the setting (or the change) of the source frequency f_{S} in the period P_{HO} will be described.

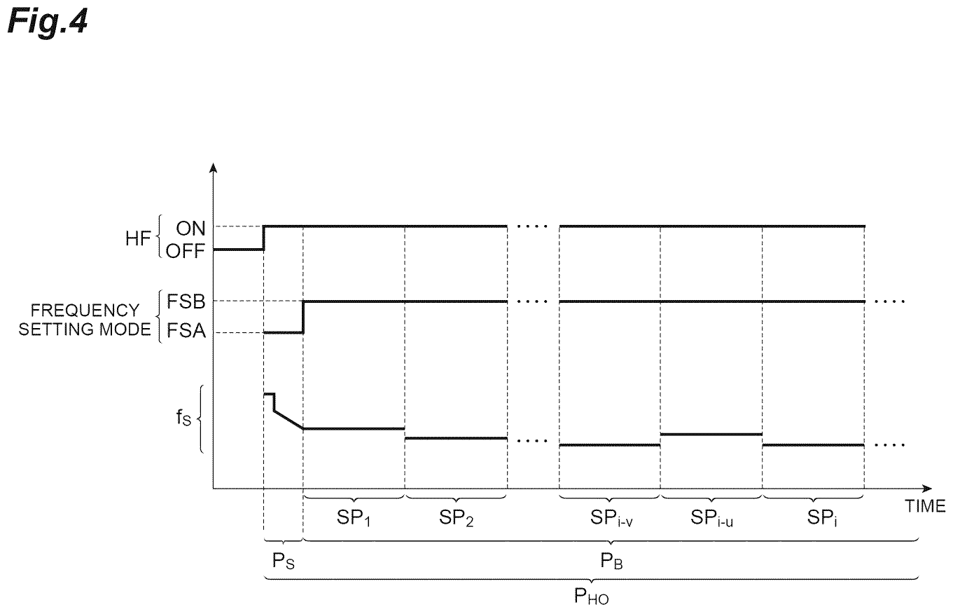

FIG. 4 is an example timing chart related to a plasma processing apparatus according to an example. FIG. 4 illustrates the timing chart of the source radio frequency power HF, a frequency setting mode, and the source frequency f_{S} in an example. In FIG. 4, “ON” of the source radio frequency power HF indicates that the source radio frequency power HF is supplied, and “OFF” of the source radio frequency power HF indicates that the supply of the source radio frequency power HF is stopped. In FIG. 4, the frequency setting mode indicates a mode of setting the source frequency f_{S}. In the example of FIG. 4, the frequency setting mode includes sequential feedback processing FSB. In the example of FIG. 4, the frequency setting mode may further include startup processing FSA.

In the example of FIG. 4, the source radio frequency power HF is supplied to generate plasma, but the electric bias EB is not used. In the example of FIG. 4, the plasma processing apparatus 1 may not include the bias power supply 32 and the matcher 32m. In addition, the plasma processing apparatus 1 may not include the pulse controller 34.

In the example, as illustrated in FIG. 4, the radio frequency power supply 31 starts the supply of the source radio frequency power HF at a start time point of the period P_{HO}. The radio frequency power supply 31 continuously supplies the source radio frequency power HF in the period P_{HO}. That is, in the example of FIG. 4, the radio frequency power supply 31 supplies a continuous wave of the source radio frequency power HF in the period P_{HO}.

In the example of FIG. 4, the period P_{HO} includes a plurality of sub-periods SP, that is, I sub-periods SP₁, SP₂, . . . , and SP_{I}. The plurality of sub-periods SP₁, SP₂, . . . , SP_{I} divide a period PB in the period P_{HO} into I sub-periods. Time lengths of the plurality of sub-periods SP may be the same as or different from each other. The time length of each of the plurality of sub-periods SP may be 10 nsec or longer and 10 μsec or shorter.

The period P_{HO} may further include a startup period P_{S} before the plurality of sub-periods SP. The startup period P_{S} may include a period of plasma ignition. The radio frequency power supply 31 may start the supply of the source radio frequency power HF at the start time point of the startup period P_{S}. The period P_{B} may be a period following the startup period P_{S}.

As illustrated in FIG. 4, the controller 30c performs the startup processing FSA in the startup period P_{S}. For example, the controller 30c changes the source frequency f_{S} in accordance with an initial frequency set from the start to the end of the startup period P_{S}. The initial frequency set is prepared in advance and is stored in a storage that can be accessed by the controller 30c. The initial frequency set may be experimentally obtained or may be determined based on the past processing result.

The controller 30c performs the sequential feedback processing FSB in the period P_{B} after the startup period P_{S}. For example, the controller 30c sets a source frequency f_{S}[i] in an i-th sub-period SPᵢ to suppress the degree of reflection of the source radio frequency power HF in the sub-period SPᵢ in accordance with the source frequency f_{S} and the degree of reflection of the source radio frequency power HF in each of one or more sub-periods before the i-th sub-period SPᵢ among the plurality of sub-periods.

In one example, the one or more sub-periods before the sub-period SPᵢ may include a sub-period SPᵢ₋ᵥ (first sub-period) and a sub-period SPᵢ₋ᵤ (second sub-period). Here, v and u are integers of 1 or greater, and v is greater than u. v may be 2, and u may be 1. When the time length of each of the plurality of sub-periods SP is short, u may be 20 or greater in order to reduce a calculation load. For example, when the time length of each of the plurality of sub-periods SP is 50 nsec, the sub-period SPᵢ is a period after 1 μsec from the sub-period SPᵢ₋ᵤ.

In the sequential feedback processing FSB, the controller 30c may set the source frequency f_{S}[i] to suppress the degree of reflection of the source radio frequency power HF in the sub-period SPᵢ in accordance with a change from the source frequency f_{S}[i-v] in the sub-period SPᵢ₋ᵥ to the source frequency f_{S}[i-u] in the sub-period SPᵢ₋ᵤ and a change from the degree of reflection of the source radio frequency power HF in the sub-period SPᵢ₋ᵥ to the degree of reflection of the source radio frequency power HF in the sub-period SPᵢ₋ᵤ.

For example, when the change from the degree of reflection of the source radio frequency power HF in the sub-period SPᵢ₋ᵥ to the degree of reflection of the source radio frequency power HF in the sub-period SPAᵢ₋ᵤ is a decrease in the degree of reflection, the controller 30c sets, as the source frequency f_{S}[i], a frequency obtained by applying a change in the same direction as a direction of a change from the source frequency f_{S}[i-v] to the source frequency f_{S}[i-u] to the source frequency f_{S}[i-u]. When the change from the degree of reflection of the source radio frequency power HF in the sub-period SPᵢ₋ᵥ to the degree of reflection of the source radio frequency power HF in the sub-period SPᵢ₋ᵤ is an increase in the degree of reflection, the controller 30c sets, as the source frequency f_{S}[i], a frequency obtained by applying a change in a direction opposite to a direction of a change from the source frequency f_{S}[i-v] to the source frequency f_{S}[i-u] to the source frequency f_{S}[i-u].

According to the example of FIG. 4, the degree of reflection of the source radio frequency power HF is reduced in a period during which the source radio frequency power HF is supplied alone and continuously. In addition, according to the example of FIG. 4, the startup until the plasma is stabilized may be accelerated. In addition, according to the example of FIG. 4, an abnormal discharge of the plasma may be suppressed. Further, according to the example of FIG. 4, since the reflection is suppressed by adjusting the source frequency f_{S}, an operation of a variable capacitor of the matcher 31m is reduced, and the life of the variable capacitor may be improved.

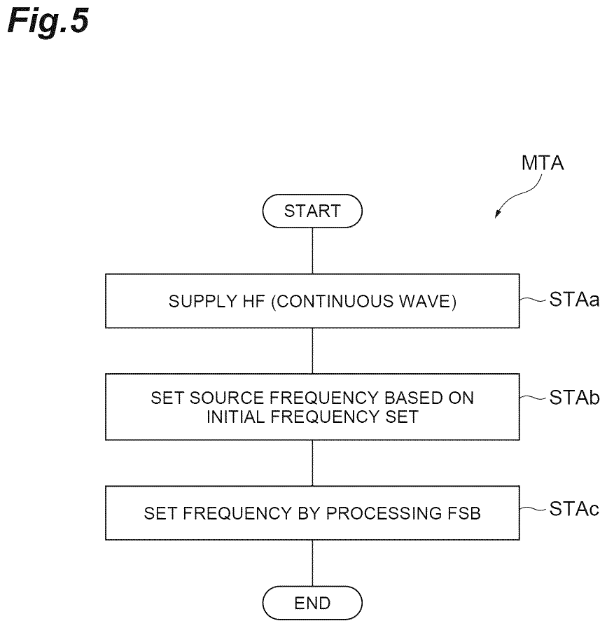

Here, reference is made to FIG. 5. FIG. 5 is a flowchart of a frequency control method according to an example. The frequency control method illustrated in FIG. 5 (hereinafter, referred to as a “method MTA”) may be performed in a state where the substrate W is placed on the substrate support 11 in the chamber 10. In the method MTA, the plasma processing may be performed on the substrate W. The plasma processing of the method MTA may include plasma etching on the substrate W.

The method MTA is started in an operation STAa. In the operation STAa, the source radio frequency power HF is supplied from the radio frequency power supply 31 to generate the plasma from the gas in the chamber 10. In the example of FIG. 4, the source radio frequency power HF is continuously supplied. That is, the continuous wave of the source radio frequency power HF is supplied.

The method MTA may further include an operation STAb. The operation STAb is performed in the startup period P_{S}. In the operation STAb, the startup processing FSA described above in relation to the example of FIG. 4 is performed.

In an operation STAc, the sequential feedback processing FSB described above in relation to the example of FIG. 4 is performed. That is, in the operation STAc, the source frequency f_{S} when the source radio frequency power HF is supplied alone is set to suppress the degree of reflection of the source radio frequency power HF, in accordance with the source frequency f_{S} and the degree of reflection of the source radio frequency power HF when the source radio frequency power HF is supplied alone beforehand.

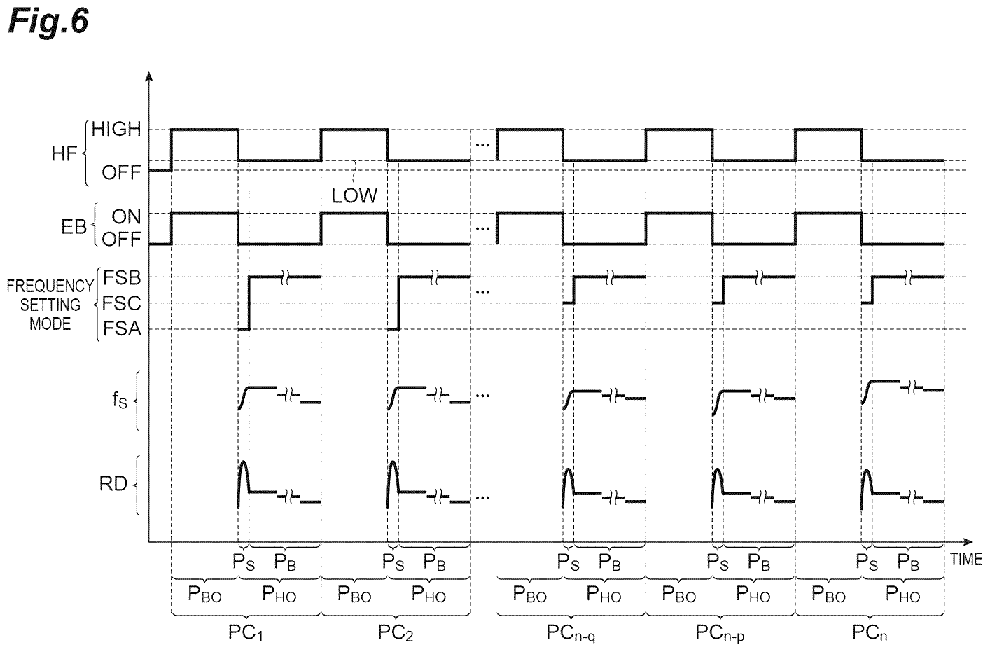

FIG. 6 is an example timing chart related to a plasma processing apparatus according to another example. FIG. 6 illustrates the timing chart of the source radio frequency power HF, the electric bias EB, the frequency setting mode, the source frequency f_{S}, and a degree of reflection RD in an example. In FIG. 6, “HIGH” of the source radio frequency power HF indicates that the power level of the source radio frequency power HF is higher than the power level of the source radio frequency power HF indicated by “LOW”. In FIG. 6, “OFF” of the source radio frequency power HF indicates that the supply of the source radio frequency power HF is stopped. In FIG. 6, “ON” of the electric bias EB indicates that the electric bias EB is supplied, and “OFF” of the electric bias EB indicates that the supply of the electric bias EB is stopped. In FIG. 6, the frequency setting mode indicates a mode of setting the source frequency f_{S}. In the example of FIG. 6, the frequency setting mode includes the startup processing FSA, the sequential feedback processing FSB, and inter-pulse feedback processing FSC.

In the example of FIG. 6, the radio frequency power supply 31 is configured to supply the source radio frequency power HF in one period of two periods in each of a plurality of cycles PC (for example, pulse cycles PC₁, PC₂, . . . ). The plurality of pulse cycles PC are present in sequence. Each of the plurality of pulse cycles PC includes a period P_{BO} and the period P_{HO}. The period P_{HO} is one period of the two periods in each of the plurality of pulse cycles PC, and the period P_{BO} is the other period.

In the example of FIG. 6, the radio frequency power supply 31 supplies the source radio frequency power HF of which the power level is indicated by “LOW” in the period P_{HO} in each of the plurality of pulse cycles PC. In addition, the radio frequency power supply 31 supplies the source radio frequency power HF of which the power level is indicated by “HIGH” in the period P_{BO} in each of the plurality of pulse cycles PC. That is, the power level of the source radio frequency power HF in the period P_{HO} in each of the plurality of pulse cycles PC is lower than the power level of the source radio frequency power HF in the period P_{BO} in each of the plurality of pulse cycles PC. Alternatively, the power level of the source radio frequency power HF in the period P_{HO} in each of the plurality of pulse cycles PC may be higher than the power level of the source radio frequency power HF in the period P_{BO} in each of the plurality of pulse cycles PC.

In the example of FIG. 6, the bias power supply 32 stops the supply of the electric bias EB to the substrate support 11 in the period P_{HO}. In addition, the bias power supply 32 supplies the electric bias EB to the substrate support 11 in the period P_{BO}. That is, the period P_{HO} is the single supply period during which the source radio frequency power HF is supplied alone without the supply of the electric bias EB.

The period P_{HO}, that is, the single supply period includes the startup period P_{S} including a start time point thereof. The startup period P_{S} may include the period of the plasma ignition. The period P_{HO} may further include the period P_{B}. The startup period P_{S} is a period before the period P_{B}. The period P_{B} may be a period following the startup period P_{S}.

As illustrated in FIG. 6, the controller 30c performs the startup processing FSA in the startup period P_{S} of each of one or more consecutive pulse cycles including at least the first pulse cycle PC₁ among the plurality of pulse cycles PC. For example, the controller 30c changes the source frequency f_{S} in accordance with the initial frequency set from the start to the end of the startup period P_{S}. The initial frequency set is prepared in advance and is stored in the storage unit that can be accessed by the controller 30c. The initial frequency set may be experimentally obtained or may be determined based on the past processing result. The number of the one or more consecutive pulse cycles including the first pulse cycle PC₁ may be 2 or more and 20 or less.

In the startup period P_{S} of each pulse cycle PC after the one or more consecutive pulse cycles including the first pulse cycle PC₁, the controller 30c performs the inter-pulse feedback processing FSC. For example, the controller 30c sets the source frequency f_{S} at each phase in the startup period P_{S} in the pulse cycle PC, to suppress the degree of reflection of the source radio frequency power HF at the same phase in the pulse cycle PC, in accordance with a change from the source frequency f_{S} at the same phase in the pulse cycle PC_{n-q} to the source frequency f_{S} at the same phase in the pulse cycle PCₙ₋ₚ and a change from the degree of reflection of the source radio frequency power HF at the same phase in the pulse cycle PC_{n-q} to the degree of reflection of the source radio frequency power HF at the same phase in the pulse cycle PCₙ₋ₚ. Here, the phase in the pulse cycle PC, is a time point in the pulse cycle PCₙ that is determined by an elapsed time from the start time point of the pulse cycle PCₙ. Therefore, the same phases in the plurality of pulse cycles are respective time points which have the same elapsed time from the start time points in the respective pulse cycles. The pulse cycle PCₙ, the pulse cycle PC_{n-q}, and the pulse cycle PCₙ₋ₚ are an n-th pulse cycle, an (n-q)-th pulse cycle, and an (n-p)-th pulse cycle among the plurality of pulse cycles PC. q and p are integers of 1 or greater, and q is greater than p. For example, q is 2, and p is 1.

Here, the phase in the startup period P_{S} in the pulse cycle PCₙ is represented by a phase αₘ. The phase αₘ is a phase after m time has elapsed from the start time point of the startup period P_{S}. In an example, when a change from the degree of reflection of the source radio frequency power HF at the phase αₘ in the startup period P_{S} in the pulse cycle PC_{n-q} to the degree of reflection of the source radio frequency power HF at the phase αₘ in the startup period P_{S} in the pulse cycle PCₙ₋ₚ is a decrease in the degree of reflection, the controller 30c sets, as the source frequency f_{S}[n, αₘ], a frequency obtained by applying a change in the same direction as a direction of a change from the source frequency f_{S}[n-q, αₘ] to the source frequency f_{S}[n-p, αₘ] to the source frequency f_{S}[n-p, αₘ]. The source frequency f_{S}[n, αₘ] represents the source frequency f_{S} at the phase αₘ in the startup period P_{S} in the pulse cycle PCₙ. When a change from the degree of reflection of the source radio frequency power HF at the phase αₘ in the startup period P_{S} in the pulse cycle PC_{n-q} to the degree of reflection of the source radio frequency power HF at the phase αₘ in the startup period P_{S} in the pulse cycle PCₙ₋ₚ is an increase in the degree of reflection, the controller 30c sets, as the source frequency f_{S}[n, αₘ], a frequency obtained by applying a change in a direction opposite to a direction of a change from the source frequency f_{S}[n-q, αₘ] to the source frequency f_{S}[n-p, αₘ] to the source frequency f_{S}[n-p, αₘ].

In the example of FIG. 6, the controller 30c may perform the sequential feedback processing FSB described above in the period P_{B} in each of the plurality of pulse cycles PC. The period PR may be started after a predetermined time has elapsed from the start of the period P_{HO}. Alternatively, the period P_{B} may be started when an amount of change in the degree of reflection is equal to or less than a designated value in the startup period P_{S}.

In the example of FIG. 6, the time length of the startup period P_{S} in each of the one or more consecutive pulse cycles including the first pulse cycle PC₁ and the time length of the startup period P_{S} in each pulse cycle after the one or more consecutive pulse cycles may be the same as or different from each other.

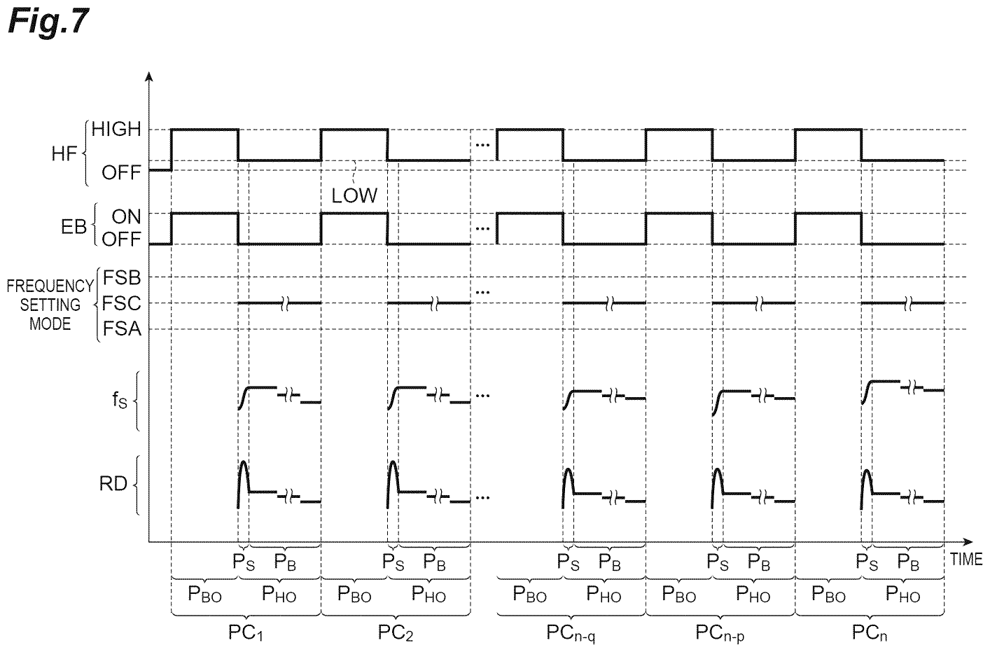

In addition, in a modification example of the example of FIG. 6, the controller 30c may first perform the startup processing FSA, then perform the inter-pulse feedback processing FSC, and then perform the sequential feedback processing FSB in the period P_{HO} of each of the plurality of pulse cycles. Alternatively, as illustrated in FIG. 7, the controller 30c may perform only the inter-pulse feedback processing FSC in the period P_{HO} of each of the plurality of pulse cycles PC. In this case, the source frequency f_{S} from the start time point to the end time point of the period P_{HO} in each of at least the first and second pulse cycles among the plurality of pulse cycles PC may be changed in accordance with another initial frequency set.

In addition, in the example of FIG. 6, the period P_{HO} in each of the plurality of pulse cycles PC may be divided into the plurality of sub-periods, and the inter-pulse feedback processing FSC described above may be applied by setting each of the plurality of sub-periods as each phase in the period P_{HO}. The time length of each of the plurality of sub-periods is, for example, 10 nsec or longer and 10 μsec or shorter. In each of the plurality of sub-periods, the source frequency f_{S} may be set to a single frequency or may be set to a plurality of frequencies.

In addition, in the example of FIG. 6, the power level of the source radio frequency power HF in the period P_{HO} of each of the plurality of pulse cycles PC may be changed to a plurality of levels in the period P_{HO}. In this case, the period P_{HO} may be divided into a plurality of divided periods for each power level of the source radio frequency power HF, and the startup processing FSA, the inter-pulse feedback processing FSC, and the sequential feedback processing FSB may be performed in each of the plurality of divided periods.

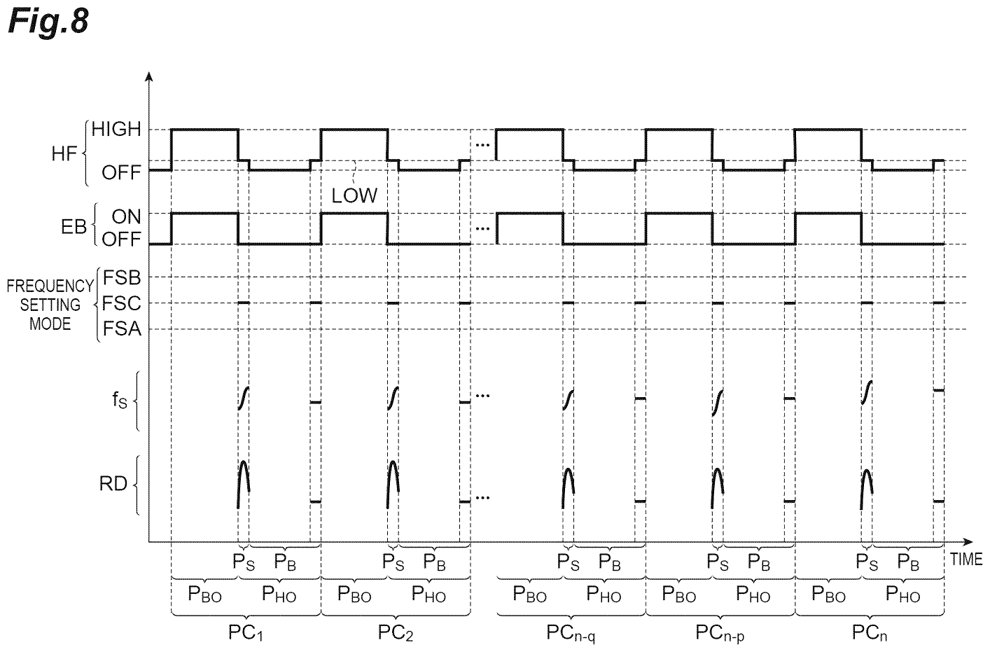

Hereinafter, reference is made to FIG. 8 to describe another modification example of the example of FIG. 6. As illustrated in FIG. 8, in another modification example of the example of FIG. 6, the power level of the source radio frequency power HF in the period P_{HO} of each of the plurality of pulse cycles PC is changed to the plurality of levels in the period P_{HO}. For example, the period P_{HO} in each of the plurality of pulse cycles PC may include one or more periods in which the power level of the source radio frequency power HF has the level indicated by “LOW” and one or more periods in which the power level of the source radio frequency power HF has the level indicated by “OFF”. The level indicated by “LOW” is lower than the level indicated by “HIGH”. The level indicated by “OFF” is zero. That is, the supply of the source radio frequency power HF is stopped during the period having the level indicated by “OFF”. In the example illustrated in FIG. 8, the source radio frequency power having the level indicated by “LOW” is supplied in two periods, that is, the period (period P_{S}) including the start time point and the period including the end time point in the period P_{HO} in each of the plurality of pulse cycles PC, and the supply of the source radio frequency power HF is stopped in a period between the two periods.

In the modification example illustrated in FIG. 8, the inter-pulse feedback processing FSC may be performed only in each period P_{HO} of the plurality of pulse cycles PC. In addition, the startup processing FSA may be performed in a period including the start time point in the period P_{HO} of each of the plurality of pulse cycles PC, and only the inter-pulse feedback processing FSC may be performed in other periods in the period P_{HO}. In this case, the source frequency f_{S} from the start time point to the end time point of the period P_{HO} in each of at least the first and second pulse cycles among the plurality of pulse cycles PC may be changed in accordance with another initial frequency set.

According to the examples of FIGS. 6 to 8, the degree of reflection of the source radio frequency power HF is reduced in the period P_{HO} during which the source radio frequency power HF is supplied alone. In addition, according to the examples of FIGS. 6 to 8, the startup until the plasma is stabilized may be accelerated. In addition, according to the examples of FIGS. 6 to 8, an abnormal discharge of the plasma may be suppressed. In addition, according to the examples of FIGS. 6 to 8, the reproducibility of an effective power level (load power level) of the source radio frequency power HF is improved. For example, when the power level of the source radio frequency power HF is changed to the plurality of power levels in the period P_{HO}, the reproducibility of the effective power level (load power level) corresponding to each power level is improved. Further, according to the examples of FIGS. 6 to 8, since the reflection is suppressed by adjusting the source frequency f_{S}, the operation of the variable capacitor of the matcher 31m is reduced, and the life of the variable capacitor may be improved.

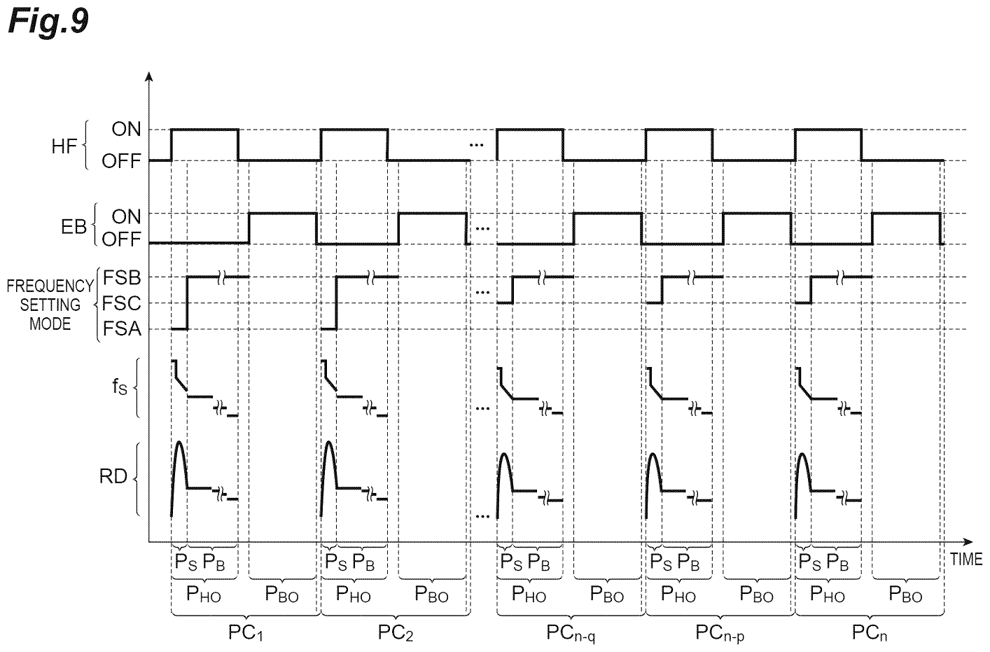

Hereinafter, a still another example related to the setting (or the change) of the source frequency f_{S} will be described with reference to FIG. 9. FIG. 9 is an example timing chart related to a plasma processing apparatus according to still another example. FIG. 9 illustrates the timing chart of the source radio frequency power HF, the electric bias EB, the frequency setting mode, the source frequency f_{S}, and the degree of reflection RD in the example. In FIG. 9, “ON” of the source radio frequency power HF indicates that the source radio frequency power HF is supplied, and “OFF” of the source radio frequency power HF indicates that the supply of the source radio frequency power HF is stopped. In FIG. 9, “ON” of the electric bias EB indicates that the electric bias EB is supplied, and “OFF” of the electric bias EB indicates that the supply of the electric bias EB is stopped. In FIG. 9, the frequency setting mode indicates a mode of setting the source frequency f_{S}. In the example of FIG. 9, the frequency setting mode includes the startup processing FSA, the sequential feedback processing FSB, and inter-pulse feedback processing FSC. Hereinafter, the example of FIG. 9 will be described in terms of a difference between the examples of FIGS. 6 to 8 and the example of FIG. 9.

In the example of FIG. 9, as in the examples of FIGS. 6 to 8, the radio frequency power supply 31 supplies the source radio frequency power HF in the period P_{HO}. In the example of FIG. 9, in contrast to the examples of FIGS. 6 to 8, the radio frequency power supply 31 stops the supply of the source radio frequency power HF in the period P_{BO}. That is, in the example of FIG. 9, the radio frequency power supply 31 stops the supply of the source radio frequency power HF in the period during which the electric bias EB is supplied.

The setting processing of the source frequency f_{S} in the period P_{HO} in the example of FIG. 9 is the same as the setting processing of the source frequency f_{S} in the period P_{HO} in the examples of FIGS. 6 to 8.

In the example of FIG. 9, the time length of the startup period P_{S} in each of the one or more consecutive pulse cycles including the first pulse cycle PC₁ and the time length of the startup period P_{S} in each pulse cycle after the one or more consecutive pulse cycles may be the same as or different from each other.

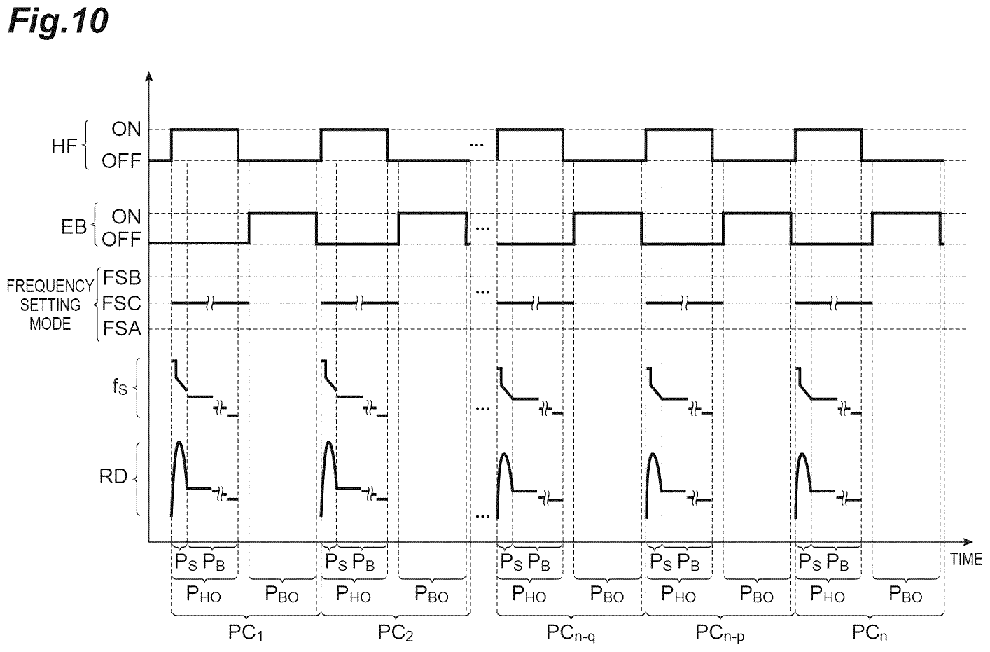

In addition, in a modification example of the example of FIG. 9, the controller 30c may first perform the startup processing FSA, then perform the inter-pulse feedback processing FSC, and then perform the sequential feedback processing FSB in the period P_{HO} of each of the plurality of pulse cycles. Alternatively, as illustrated in FIG. 10, the controller 30c may perform only the inter-pulse feedback processing FSC in the period P_{HO} of each of the plurality of pulse cycles PC. In this case, the source frequency f_{S} from the start time point to the end time point of the period P_{HO} in each of at least the first and second pulse cycles among the plurality of pulse cycles PC may be changed in accordance with another initial frequency set.

In addition, in the examples of FIGS. 9 and 10, the period P_{HO} in each of the plurality of pulse cycles PC may be divided into the plurality of sub-periods, and the inter-pulse feedback processing FSC described above may be applied by setting each of the plurality of sub-periods as each phase in the period P_{HO}. The time length of each of the plurality of sub-periods is, for example, 10 nsec or longer and 10 μsec or shorter. In each of the plurality of sub-periods, the source frequency f_{S} may be set to a single frequency or may be set to a plurality of frequencies.

In addition, in the examples of FIGS. 9 and 10, the power level of the source radio frequency power HF in the period P_{HO} of each of the plurality of pulse cycles PC may be changed to the plurality of levels in the period P_{HO}. In this case, the period P_{HO} may be divided into a plurality of divided periods for each power level of the source radio frequency power HF, and the startup processing FSA, the inter-pulse feedback processing FSC, and the sequential feedback processing FSB may be performed in each of the plurality of divided periods.

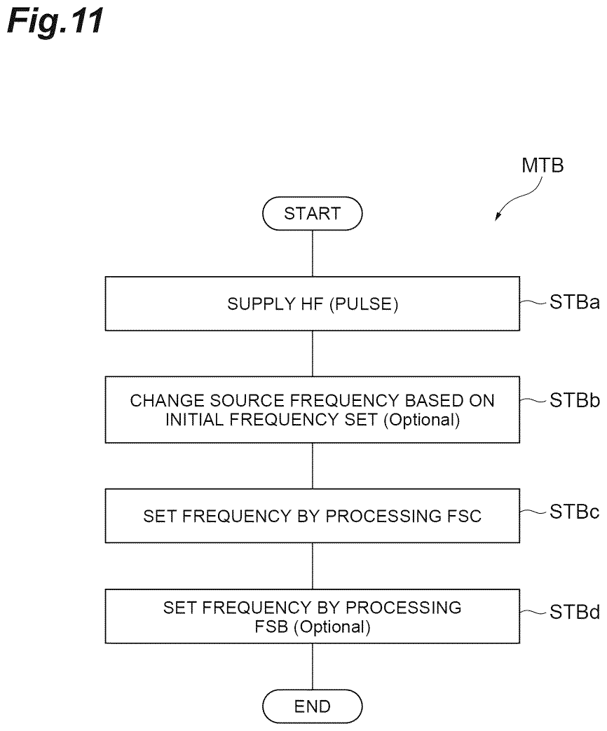

Hereinafter, a frequency control method according to the examples relating to FIGS. 6 to 10 will be described with reference to FIG. 11. FIG. 11 is a flowchart of the frequency control method according to another example. FIG. 11 illustrates a flow of the frequency control method in the period P_{HO} of each of the plurality of pulse cycles PC. The frequency control method illustrated in FIG. 11 (hereinafter, referred to as a “method MTB”) may be performed in a state where the substrate W is placed on the substrate support 11 in the chamber 10. In the method MTB, the plasma processing may be performed on the substrate W. The plasma processing of the method MTB may include the plasma etching on the substrate W.

The method MTB is started in an operation STBa. The operation STBa is performed in the period P_{HO} in each of the plurality of pulse cycles PC. In the operation STBa, the pulse of the source radio frequency power HF is supplied from the radio frequency power supply 31 to generate the plasma from the gas in the chamber 10.

The method MTB may further include an operation STBb. The operation STBb is performed in the startup period P_{S} of each of the one or more consecutive pulse cycles including the first pulse cycle among the plurality of pulse cycles PC. In the operation STBb, the startup processing FSA described above is performed.

In an operation STBc, the inter-pulse feedback processing FSC described above is performed. The inter-pulse feedback processing FSC may be performed in the startup period P_{S} in each pulse cycle after the one or more consecutive pulse cycles including the first pulse cycle among the plurality of pulse cycles PC. Alternatively, the inter-pulse feedback processing FSC may be performed in the entire period P_{HO} of each of the plurality of pulse cycles PC. Alternatively, the inter-pulse feedback processing FSC may be performed after the startup processing FSA in the period P_{HO} of each of the plurality of pulse cycles PC.

The method MTB may further include an operation STBd. In the operation STBd, the sequential feedback processing FSB described above is performed. The sequential feedback processing FSB may be performed after the startup period P_{S} in the period P_{HO} in the plurality of pulse cycles PC. Alternatively, the sequential feedback processing FSB may be performed after the inter-pulse feedback processing FSC performed after the startup processing FSA in the period P_{HO} in the plurality of pulse cycles PC.

While various examples have been described above, various additions, omissions, substitutions and changes may be made without being limited to the examples described above. Elements of the different examples may be combined to form another example.

For instance, a plasma processing apparatus in another example may be an inductively coupled plasma processing apparatus. In the inductively coupled plasma processing apparatus, the source radio frequency power HF is supplied to an antenna.

Here, various examples in the disclosure are described in the following [E1] to [E14].

[E1] A plasma processing apparatus including:
a chamber;
a substrate support provided in the chamber;
a radio frequency power supply configured to supply a source radio frequency power to generate a plasma from a gas in the chamber; and
a controller,
wherein the controller is configured to set a source frequency of the source radio frequency power when the source radio frequency power is supplied alone to suppress a degree of reflection of the source radio frequency power in accordance with the source frequency and the degree of reflection of the source radio frequency power when the source radio frequency power is supplied alone beforehand.

[E2] The plasma processing apparatus according to E1, wherein
the radio frequency power supply is configured to continuously supply the source radio frequency power in a single supply period thereof,
the single supply period includes a plurality of sub-periods, and
the controller is configured to set the source frequency in an i-th sub-period among the plurality of sub-periods to suppress the degree of reflection of the source radio frequency power in accordance with the source frequency and the degree of reflection of the source radio frequency power in each of one or more sub-periods before the i-th period among the plurality of sub-periods.

[E3] The plasma processing apparatus according to E2, wherein
the one or more sub-periods include a first sub-period and a second sub-period after the first sub-period, and
the controller is configured to
   set the source frequency in the second sub-period to a frequency different from the source frequency in the first sub-period, and
   set the source frequency in the i-th sub-period to suppress the degree of reflection of the source radio frequency power in accordance with a change from the source frequency in the first sub-period to the source frequency in the second sub-period and a change from the degree of reflection of the source radio frequency power in the first sub-period to the degree of reflection of the source radio frequency power in the second sub-period.

[E4] The plasma processing apparatus according to E2 or E3, wherein
the single supply period further includes a startup period before the plurality of sub-periods, the startup period including a start time point of the single supply period, and
the controller is configured to change the source frequency from a start to an end of a startup period in accordance with an initial frequency set.

[E5] The plasma processing apparatus according to any one of E2 to E4, further including:
a bias power supply electrically coupled to the substrate support and configured to supply an electric bias for ion attraction to the substrate support,
wherein the single supply period is a period during which the electric bias from the bias power supply is not supplied to the substrate support.

[E6] The plasma processing apparatus according to E1, further including:
a bias power supply electrically coupled to the substrate support and configured to supply an electric bias for ion attraction to the substrate support,
wherein the radio frequency power supply is configured to supply the source radio frequency power in one period of two periods in each of a plurality of pulse cycles,
the bias power supply is configured to stop the supply of the electric bias to the substrate support in the one period of the two periods in each of the plurality of pulse cycles and supply the electric bias to the substrate support in an other period of the two periods,
the one period includes a startup period including a start time point thereof, and
the controller is configured to set the source frequency at each phase in the startup period in the one period in an n-th pulse cycle among the plurality of pulse cycles to suppress the degree of reflection of the source radio frequency power in accordance with a change from the source frequency at a same phase in an (n-q)-th pulse cycle among the plurality of pulse cycles to the source frequency at the same phase in an (n-p)-th pulse cycle among the plurality of pulse cycles and a change from the degree of reflection of the source radio frequency power at the same phase in the (n-q)-th pulse cycle to the degree of reflection of the source radio frequency power at the same phase in the (n-p)-th pulse cycle, where q and p are integers of 1 or greater satisfying q>p.

[E7] The plasma processing apparatus according to E6, wherein the controller is configured to change the source frequency in accordance with an initial frequency set during a period from a start to an end of the startup period in each of one or more consecutive pulse cycles including at least a first pulse cycle among the plurality of pulse cycles.

[E8] The plasma processing apparatus according to E6 or E7, wherein
each of the plurality of pulse cycles includes a plurality of sub-periods after the startup period, and
the controller is configured to set the source frequency in an i-th sub-period among the plurality of sub-periods of each of the plurality of pulse cycles to suppress the degree of reflection of the source radio frequency power in accordance with the source frequency and the degree of reflection of the source radio frequency power in each of one or more sub-periods before the i-th period among the plurality of sub-periods.

[E9] The plasma processing apparatus according to E8, wherein
the one or more sub-periods include a first sub-period and a second sub-period after the first sub-period, and
the controller is configured to
   set the source frequency in the second sub-period to a frequency different from the source frequency in the first sub-period, and
   set the source frequency in the i-th sub-period to suppress the degree of reflection of the source radio frequency power in accordance with a change from the source frequency in the first sub-period to the source frequency in the second sub-period and a change from the degree of reflection of the source radio frequency power in the first sub-period and the degree of reflection of the source radio frequency power in the second sub-period.

[E10] The plasma processing apparatus according to any one of E6 to E9, wherein the radio frequency power supply is configured to stop the supply of the source radio frequency power in the other period.

[E11] The plasma processing apparatus according to any one of E6 to E9, wherein the radio frequency power supply is configured to supply the source radio frequency power in the other period.

[E12] The plasma processing apparatus according to E11, wherein a power level of the source radio frequency power in the one period is lower than a power level of the source radio frequency power in the other period.

[E13] A power supply system including:
a radio frequency power supply configured to supply a source radio frequency power to generate a plasma from a gas in a chamber of a plasma processing apparatus; and
a controller,
wherein the controller is configured to set a source frequency of the source radio frequency power when the source radio frequency power is supplied alone to suppress a degree of reflection of the source radio frequency power in accordance with the source frequency and the degree of reflection of the source radio frequency power when the source radio frequency power is supplied alone beforehand.

[E14] A frequency control method including:
(a) supplying a source radio frequency power from a radio frequency power supply to generate a plasma from a gas in a chamber of a plasma processing apparatus; and
(b) setting a source frequency of the source radio frequency power when the source radio frequency power is supplied alone in the (a) to suppress a degree of reflection of the source radio frequency power in accordance with the source frequency and the degree of reflection of the source radio frequency power when the source radio frequency power is supplied alone beforehand.

From the foregoing description, it will be appreciated that various examples of the present disclosure have been described herein for purposes of illustration, and that various modifications may be made without departing from the scope and spirit of the present disclosure. Accordingly, the various examples disclosed herein are not intended to be limiting, with the true scope and spirit being indicated by the following claims.

What is claimed is:

1. A plasma processing apparatus comprising:
a chamber;
a radio frequency power supply configured to supply a radio frequency power over a plurality of cycles that are repeated to generate a plasma from a gas located in the chamber, wherein for each of the plurality of cycles the radio frequency power is supplied continuously during a single supply period that comprises a number of sub-periods including an i-th sub-period and one or more sub-periods which precede the i-th sub-period; and
circuitry configured to set a frequency of the radio frequency power in the i-th sub-period for each of the plurality of cycles to suppress a degree of reflection of the radio frequency power in the i-th sub-period based, at least in part, on both the frequency of the radio frequency power and the degree of reflection of the radio frequency power in each of the one or more sub-periods that precede the i-th sub-period for each of the plurality of cycles.

2. The plasma processing apparatus according to claim 1, wherein the one or more sub-periods that precede the i-th sub-period include a first sub-period followed by a second sub-period, and
wherein the circuitry is configured to:
set the frequency of the radio frequency power in the first sub-period to a first frequency;
set the frequency of the radio frequency power in the second sub-period to a second frequency that is different than the first frequency; and
set the frequency of the radio frequency power in the i-th sub-period, to suppress the degree of reflection of the radio frequency power in the i-th sub-period based on both a change from the first frequency to the second frequency, and a change from the degree of reflection of the radio frequency power in the first sub-period to the degree of reflection of the radio frequency power in the second sub-period.

3. The plasma processing apparatus according to claim 1, wherein the circuitry is configured to set the frequency of the radio frequency power at each phase in a startup period before the number of sub-periods of the single supply period in an n-th cycle among the plurality of cycles, to suppress the degree of reflection of the radio frequency power based, at least in part, on both the frequency of the radio frequency power and the degree of reflection of the radio frequency power at a same phase in the startup period in one or more cycles before the n-th cycle among the plurality of cycles.

4. The plasma processing apparatus according to claim 3,
wherein the circuitry is configured to set the frequency of the radio frequency power at each phase in the startup period of the single supply period during the n-th cycle, to suppress the degree of reflection of the radio frequency power based, at least in part, on both a change from the frequency of the radio frequency power at the same phase in the startup period of the single supply period during the (n-q)-th cycle to the frequency of the radio frequency power at the same phase in the startup period of the single supply period during the (n-p)-th cycle and a change from the degree of reflection of the radio frequency power at the same phase in the startup period of the single supply period during the (n-q)-th cycle to the degree of reflection of the radio frequency power at the same phase in the startup period of the single supply period during the (n-p)-th cycle.

5. The plasma processing apparatus according to claim 3, wherein the circuitry is configured to change the frequency of the radio frequency power from a start to an end of the startup period in each of one or more consecutive cycles including at least a first cycle among the plurality of cycles based, at least in part, on an initial frequency set.

6. The plasma processing apparatus according to claim 1, wherein the circuitry is configured to change the frequency from a start to an end of a startup period before the number of sub-periods in the single supply period in each of one or more consecutive cycles including at least a first cycle among the plurality of cycles based, at least in part, on a predetermined initial frequency set.

7. The plasma processing apparatus according to claim 1, further comprising a bias power supply electrically coupled to a substrate support in the chamber and configured to supply an electric bias for ion attraction to the substrate support,
wherein the single supply period is a period during which the electric bias from the bias power supply is not supplied to the substrate support.

8. The plasma processing apparatus according to claim 1, further comprising a bias power supply electrically coupled to a substrate support in the chamber and configured to supply an electric bias for ion attraction to the substrate support,
wherein the radio frequency power supply is configured to supply the radio frequency power in the single supply period which is one period of two periods in each of the plurality of cycles, and
the bias power supply is configured to stop the supply of the electric bias to the substrate support in the one period of the two periods in each of the plurality of cycles and to supply the electric bias to the substrate support in an other period of the two periods.

9. The plasma processing apparatus according to claim 8, wherein the radio frequency power supply is configured to stop the supply of the radio frequency power in the other period.

10. The plasma processing apparatus according to claim 8, wherein the radio frequency power supply is configured to supply the radio frequency power in the other period.

11. The plasma processing apparatus according to claim 10, wherein a power level of the radio frequency power in the one period is lower than a power level of the radio frequency power in the other period.

12. A power supply system for generating a plasma from a gas, the power supply system comprising:
a radio frequency power supply configured to supply a radio frequency power over a plurality of pulse cycles that are repeated to generate the plasma, wherein for each of the plurality of pulse cycles the radio frequency power is supplied continuously during a single supply period that comprises a number of sub-periods including an i-th sub-period and one or more sub-periods which precede the i-th sub-period; and
a controller configured to set a frequency of the radio frequency power in the i-th sub-period for each of the plurality of pulse cycles to suppress a degree of reflection of the radio frequency power in the i-th sub-period based, at least in part, on both the frequency of the radio frequency power and the degree of reflection of the radio frequency power in each of the one or more sub-periods that precede the i-th sub-period for each of the plurality of pulse cycles.

13. The power supply system according to claim 12, wherein the controller is configured to set the frequency of the radio frequency power at each phase in a startup period before the number of sub-periods of the single supply period in an n-th cycle among the plurality of pulse cycles, to suppress the degree of reflection of the radio frequency power based, at least in part, on both the frequency of the radio frequency power and the degree of reflection of the radio frequency power at a same phase in the startup period in one or more cycles before the n-th cycle among the plurality of pulse cycles.

14. The power supply system according to claim 13, wherein the controller is configured to change the frequency of the radio frequency power from a start to an end of the startup period in each of one or more consecutive cycles including at least a first cycle among the plurality of pulse cycles based, at least in part, on an initial frequency set.

15. The power supply system according to claim 12, wherein the controller is configured to change the frequency from a start to an end of a startup period before the number of sub-periods in the single supply period in each of one or more consecutive cycles including at least a first cycle among the plurality of pulse cycles based, at least in part, on a predetermined initial frequency set.

16. A frequency control method for generating a plasma, the method comprising:
supplying a radio frequency power over a plurality of cycles that are repeated to generate the plasma from a gas located in a chamber, wherein for each of the plurality of cycles the radio frequency power is supplied continuously during a single supply period that comprises a number of sub-periods including an i-th sub-period and one or more sub-periods which precede the i-th sub-period; and
setting a frequency of the radio frequency power in the i-th sub-period for each of the plurality of cycles to suppress a degree of reflection of the radio frequency power in the i-th sub-period based, at least in part, on both the frequency of the radio frequency power and the degree of reflection of the radio frequency power in each of the one or more sub-periods that precede the i-th sub-period for each of the plurality of cycles.

17. The frequency control method according to claim 16, further comprising setting the frequency of the radio frequency power at each phase in a startup period before the number of sub-periods of the single supply period in an n-th cycle among the plurality of cycles, to suppress the degree of reflection of the radio frequency power based, at least in part, on both the frequency of the radio frequency power and the degree of reflection of the radio frequency power at a same phase in the startup period in one or more cycles before the n-th cycle among the plurality of cycles.

18. The frequency control method according to claim 17, further comprising changing the frequency of the radio frequency power from a start to an end of the startup period in each of one or more consecutive cycles including at least a first cycle among the plurality of cycles based, at least in part, on an initial frequency set.

19. The frequency control method according to claim 16, further comprising changing the frequency from a start to an end of a startup period before the number of sub-periods in the single supply period in each of one or more consecutive cycles including at least a first cycle among the plurality of cycles based, at least in part, on a predetermined initial frequency set.

20. The frequency control method according to claim 16, wherein the one or more sub-periods that precede the i-th sub-period include a first sub-period followed by a second sub-period, and
wherein the method further comprises:
setting the frequency of the radio frequency power in the first sub-period to a first frequency;
setting the frequency of the radio frequency power in the second sub-period to a second frequency that is different than the first frequency; and
setting the frequency of the radio frequency power in the i-th sub-period, to suppress the degree of reflection of the radio frequency power in the i-th sub-period based on both a change from the first frequency to the second frequency, and a change from the degree of reflection of the radio frequency power in the first sub-period to the degree of reflection of the radio frequency power in the second sub-period.
